(19) United States
(12) Patent Application Publication
(10) Pub. No.: US 2002/0151195 A1
(43) Pub. Date: Oct. 17, 2002

(54) Power interconnect method utilizing a flexible circuit between a voltage regulation module and an integrated circuit substrate

(75) Inventors: Joseph Ted DiBene II, Oceanside, CA (US); David H. Hartke, Durango, CO (US)

Correspondence Address: GATES & COOPER LLP, HOWARD HUGHES CENTER, 6701 CENTER DRIVE WEST, SUITE 1050, LOS ANGELES, CA, 90045, US

(73) Assignee: INCEP Technologies, Inc.

(21) Appl. No.: 10/147,395

(22) Filed: May 16, 2002

Related U.S. Application Data
(63) Continuation-in-part of application No. 09/885,780, filed on Jun. 19, 2001, now abandoned.
(63) Continuation-in-part of application No. 09/353,428, filed on Jul. 15, 1999, now Pat. No. 6,304,450.
(63) Continuation-in-part of application No. 09/432,878, filed on Nov. 2, 1999, now Pat. No. 6,356,448.
(63) Continuation-in-part of application No. 09/353,428, filed on Jul. 15, 1999, now Pat. No. 6,304,450.
(63) Continuation-in-part of application No. 09/727,016, filed on Nov. 28, 2000.
(63) Continuation-in-part of application No. 09/785,892, filed on Feb. 16, 2001.
(63) Continuation-in-part of application No. 09/798,541, filed on Mar. 2, 2001.
(63) Continuation-in-part of application No. 09/727,016, filed on Nov. 28, 2000.
(63) Continuation-in-part of application No. 09/785,892, filed on Feb. 16, 2001.
(63) Continuation-in-part of application No. 09/432,878, filed on Nov. 2, 1999, now Pat. No. 6,356,448.
(63) Continuation-in-part of application No. 09/353,428, filed on Jul. 15, 1999, now Pat. No. 6,304,450.
(60) Provisional application No. 60/301,753, filed on Jun. 27, 2001.
(60) Provisional application No. 60/304,930, filed on Jul. 11, 2001.
(60) Provisional application No. 60/291,749, filed on May 16, 2001.
(60) Provisional application No. 60/291,772, filed on May 16, 2001.
(60) Provisional application No. 60/292,125, filed on May 18, 2001.
(60) Provisional application No. 60/299,573, filed on Jun. 19, 2001.
(60) Provisional application No. 60/301,753, filed on Jun. 27, 2001.
(60) Provisional application No. 60/304,929, filed on Jul. 11, 2001.
(60) Provisional application No. 60/304,930, filed on Jul. 11, 2001.
(60) Provisional application No. 60/310,038, filed on Aug. 3, 2001.
(60) Provisional application No. 60/313,338, filed on Aug. 17, 2001.
(60) Provisional application No. 60/338,004, filed on Nov. 8, 2001.
(60) Provisional application No. 60/377,557, filed on May 3, 2002.
(60) Provisional application No. 60/361,554, filed on Mar. 4, 2002.
(60) Provisional application No. 60/359,504, filed on Feb. 25, 2002.
(60) Provisional application No. 60/167,792, filed on Nov. 29, 1999.
(60) Provisional application No. 60/171,065, filed on Dec. 16, 1999.
(60) Provisional application No. 60/183,474, filed on Feb. 18, 2000.
(60) Provisional application No. 60/187,777, filed on Mar. 8, 2000.
(60) Provisional application No. 60/196,059, filed on Apr. 10, 2000.
(60) Provisional application No. 60/219,506, filed on Jul. 20, 2000.
(60) Provisional application No. 60/219,813, filed on Jul. 21, 2000.
(60) Provisional application No. 60/222,386, filed on Aug. 2, 2000.
(60) Provisional application No. 60/222,407, filed on Aug. 2, 2000.
(60) Provisional application No. 60/232,971, filed on Sep. 14, 2000.
(60) Provisional application No. 60/183,474, filed on Feb. 18, 2000.
(60) Provisional application No. 60/186,769, filed on Mar. 3, 2000.
(60) Provisional application No. 60/187,777, filed on Mar. 8, 2000.
(60) Provisional application No. 60/196,059, filed on Apr. 10, 2000.
(60) Provisional application No. 60/219,506, filed on Jul. 20, 2000.
(60) Provisional application No. 60/219,813, filed on Jul. 21, 2000.
(60) Provisional application No. 60/222,386, filed on Aug. 2, 2000.
(60) Provisional application No. 60/222,407, filed on Aug. 2, 2000.
(60) Provisional application No. 60/232,971, filed on Sep. 14, 2000.
(60) Provisional application No. 60/251,222, filed on Dec. 4, 2000.
(60) Provisional application No. 60/251,223, filed on Dec. 4, 2000.
(60) Provisional application No. 60/251,184, filed on Dec. 4, 2000.
(60) Provisional application No. 60/266,941, filed on Feb. 6, 2001.
(60) Provisional application No. 60/183,474, filed on Feb. 18, 2000.

(51) Int. Cl. H05K 1/00

(52) U.S. Cl. 439/67

(57) ABSTRACT

A method and apparatus for providing power from a first circuit board to a second circuit board is disclosed. The apparatus comprises a flex circuit having a plurality of conductive paths formed by a plurality of first conductive areas electrically coupled to a plurality of second conductive areas wherein the plurality of first conductive areas permanently and electrically coupled to a plurality of first circuit board conductive pads and the plurality of second conductive areas disconnectably and electrically coupleable to at least one second circuit board conductive pad.

### CROSS-REFERENCE TO RELATED APPLICATIONS

This application claims benefit of the following U.S. Provisional Patent applications, which are hereby incorporated by reference herein:

Application Serial No. 60/301,753, entitled “INTEGRATED POWER DELIVERY USING HIGH PERFORMANCE LINEAR REGULATORS ON PACKAGE WITH A MICROPROCESSOR” by Joseph T. DiBene II, David H. Hartke, and Carl E. Hoge, filed Jun. 27, 2001;

Application Serial No. 60/304,930, entitled “Micro-i-PAK” by Joseph T. DiBene II, Carl E. Hoge, David H. Hartke, and Edward J. Derian, filed Jul. 11, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEATSINK FOR LOW PRESSURE DROP HIGH PERFORMANCE THERMAL MANAGEMENT ELECTRONIC ASSEMBLY SOLUTIONS,” by Joseph T. DiBene II, Farhad Raiszadeh, filed May 18, 2001;

Application Serial No. 60/299,573, entitled “IMPROVED MICRO-I-PAK STACK-UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001;

Application Serial No. 60/304,930, entitled “MICRO-I-PAK,” by Joseph T. DiBene II, Carl E. Hoge, David H. Hartke, and Edward J. Derian, filed Jul. 11, 2001;

Application Serial No. 60/310,038, entitled “TOOL-LESS CONCEPTS FOR BORREGO,” by Edward J. Derian and Joseph T. DiBene II, filed Aug. 3, 2001;

Application Serial No. 60/313,338, entitled “TOOL-LESS PRISM IPA ASSEMBLY TO SUPPORT IA64 MCKINLEY MICROPROCESSOR,” by David H. Hartke and Edward J. Derian, filed Aug. 17, 2001;

Application Serial No. 60/338,004, entitled “MICRO-SPRING CONFIGURATIONS FOR POWER DELIVERY FROM VOLTAGE REGULATOR MODULES TO INTEGRATED CIRCUITS AND MICROPROCESSORS,” by Joseph T. DiBene II, David H. Hartke, Carl E. Hoge, and Edward J. Derian, filed Nov. 8, 2001;

Application Ser. No. ______, entitled “METHOD AND APPARATUS FOR SURFACE POWER DELIVERY,” by Edward J. Derian, filed Apr. 30, 2002;

Application Serial No. 60/377,557, entitled “EVRM STACK-UP, POWER DELIVERY SOLUTION,” by David H. Hartke and Joseph T. DiBene II, filed May 3, 2002;

Application Serial No. 60/361,554, entitled “RIGHT ANGLE POWER CONNECTOR ARCHITECTURE,” by David H. Hartke, filed Mar. 4, 2002; and

Application Serial No. 60/359,504, entitled “HIGH EFFICIENCY VRM CIRCUIT CONSTRUCTIONS FOR LOW VOLTAGE, HIGH CURRENT ELECTRONIC DEVICES,” by Philip M. Harris, filed Feb. 25, 2002,

This patent application is also continuation-in-part of the following co-pending and commonly assigned patent applications, each of which applications are hereby incorporated by reference herein:

Application Ser. No. 09/885,780, entitled “INTER-CIRCUIT ENCAPSULATED PACKAGING,” by Joseph T. DiBene II and David H. Hartke, filed Jun. 19, 2001, which is a continuation in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of

Application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000, which claims priority to the following U.S. Provisional Patent Applications:

Application Serial No. 60/167,792, entitled “EMI CONTAINMENT USING INTER-CIRCUIT ENCAPSULATED PACKAGING TECHNOLOGY,” by Joseph T. DiBene II and David H. Hartke, filed Nov. 29, 1999;

Application Serial No. 60/171,065, entitled “INTER-CIRCUIT ENCAPSULATED PACKAGING TECHNOLOGY,” by Joseph T. DiBene II and David H. Hartke, filed Dec. 16, 1999;

Application Serial No. 60/183,474, entitled “DIRECT ATTACH POWER/THERMAL WITH INCEP,” by Joseph T. DiBene II and David H. Hartke, filed Feb. 18, 2000;

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,506, entitled “HIGH PERFORMANCE THERMAL MECHANICAL INTERFACE,” by Wendell C. Johnson, David H. Hartke and Joseph T. DiBene II, filed Jul. 20, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEAT SINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001, which claims priority to the following Provisional Patent Applications;

Application Serial No. 60/183,474, entitled “DIRECT ATTACH POWER/THERMAL WITH INCEP,” by Joseph T. DiBene RI and David H. Hartke, filed Feb. 18, 2000;

Application Serial No. 60/186,769, entitled “THERMACEP SPRING BEAM,” by Joseph T. DiBene II and David H. Hartke, filed Mar. 3, 2000;

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,506, entitled “HIGH PERFORMANCE THERMAL MECHANICAL INTERFACE,” by Wendell C. Johnson, David H. Hartke and Joseph T. DiBene II, filed Jul. 20, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEAT SINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000; and

Application Serial No. 60/266,941, entitled “MECHANICAL INTERCONNECTION TECHNOLOGIES USING FLEX CABLE INTERCONNECT FOR DELIVERY IN ‘INCEP’ INTEGRATED ARCHITECTURE,” by David H. Hartke, James M. Broder, Joseph T. DiBene II, filed Feb. 6, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene Il, David H. Hartke, Wendell C. Johnson, and Edward J. Derian, filed Mar. 2, 2001, which is a continuation-in-part of application Ser. No. 09/727,016, entitled “EMI CONTAINMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450, and which claims priority to the following U.S. Provisional Patent Applications:

Application Serial No. 60/183,474, entitled “DIRECT ATTACH POWER/THERMAL WITH INCEP,” by Joseph T. DiBene II and David H. Hartke, filed Feb. 18, 2000;

Application Serial No. 60/186,769, entitled “THERMACEP SPRING BEAM,” by Joseph T. DiBene II and David H. Hartke, filed Mar. 3, 2000;

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,506, entitled “HIGH PERFORMANCE THERMAL MECHANICAL INTERFACE,” by Wendell C. Johnson, David H. Hartke and Joseph T. DiBene II, filed Jul. 20, 2000;

Application Serial No. 60/219,813, entitled “HIGH-CURRENT MICROPROCESSOR POWER DELIVERY SYSTEMS,” by Joseph T. DiBene II filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000; and

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001;

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001, which is a continuation in part of the following patent applications:

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450; and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000; and

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001, which is a continuation in part of the following patent applications:

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001, which is a continuation-in-part of application Ser. No. 09/727,016, entitled “EMI CONTAINMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450, and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEAT-SINK COMBINATION FOR HIGH EFFICIENCY THERMAL MANAGEMENT,” by David H. Hartke and Joseph T. DiBene II, filed Aug. 2, 2000;

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000; and

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001;

Application Ser. No. 09/910,524, entitled “HIGH PERFORMANCE THERMAL/MECHANICAL INTERFACE FOR FIXED-GAP REFERENCES FOR HIGH HEAT FLUX AND POWER SEMICONDUCTOR APPLICATIONS”, by Joseph T. DiBene II, David H. Hartke, Wendell C. Johnson, Farhad Raiszadeh, Edward J. Darien and Jose B. San Andres, filed Jul. 20, 2001, which is a continuation in part of the following patent applications:

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000, which claims priority to the following U.S. Provisional Patent Applications;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450, and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/219,506, entitled “HIGH PERFORMANCE THERMAL MECHANICAL INTERFACE,” by Wendell C. Johnson, David H. Hartke and Joseph T. DiBene II, filed Jul. 20, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000;

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001;

Application Serial No. 60/277,369, entitled “THERMAL-MECHANICAL MEASUREMENT AND ANALYSIS OF AN ADVANCED THERMAL INTERFACE MATERIAL CONSTRUCTION,” by Farhad Raiszadeh and Edward J. Derian, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEAT SINK FOR LOW PRESSURE DROP HIGH PERFORMANCE THERMAL MANAGEMENT ELECTRONIC ASSEMBLY SOLUTIONS,” by Joseph T. DiBene II and Farhad Raiszadeh, filed May 18, 2001;

Application Serial No. 60/299,573, entitled “MICRO I-PAK STACK UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001; and

Application Serial No. 60/304,930, entitled “MICRO I-PAK,” by Joseph T. DiBene II, Carl E. Hoge, David H. Hartke, Edward J. Derian, filed Jul. 11, 2001;

Application Ser. No. 09/818,173, entitled “INTER-CIRCUIT ENCAPSULATED PACKAGING,” by David H. Hartke and Joseph T. DiBene II, filed Mar. 26, 2001, which is a continuation in part of the following patent applications:

Application Ser. No. 09/801,437, entitled “METHOD AND APPARATUS FOR DELIVERING POWER TO HIGH PERFORMANCE ELECTRONIC ASSEMBLIES” by Joseph T. DiBene UI, David H. Hartke, Carl E. Hoge, James M. Broder, Edward J. Derian, Joseph S. Riel, and Jose B. San Andres, filed Mar. 8, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001, which is a continuation-in-part of application Ser. No. 09/727,016, entitled “EMI CONTAINMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450, and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000; and

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001; and

Application Serial No. 60/277,369, entitled “THERMAL-MECHANICAL MEASUREMENT AND ANALYSIS OF AN ADVANCED THERMAL INTERFACE MATERIAL CONSTRUCTION,” by Farhad Raiszadeh and Edward J. Derian, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND A SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEATSINK FOR LOW PRESSURE DROP HIGH PERFORMANCE THERMAL MANAGEMENT ELECTRONIC ASSEMBLY SOLUTIONS,” by Joseph T. DiBene II and Farhad Raiszadeh, filed May 18, 2001;

Application Serial No. 60/299,573, entitled “MICRO I-PAK STACK UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001;

Application Serial No. 60/304,930, entitled “MICRO I-PAK,” by Joseph T. DiBene II, Carl E. Hoge, David H. Hartke, Edward J. Derian, filed Jul. 11, 2001;

Application Ser. No. 09/921,153 entitled “VAPOR CHAMBER WITH INTEGRATED PIN ARRAY”, by Joseph T. DiBene, II and Farhad Raiszadeh, filed on Aug. 2, 2001, which is a continuation in part of the following patent applications:

Application Ser. No. 09/921,152, entitled “HIGH SPEED AND HIGH DENSITY CIRCULAR CONNECTOR FOR BOARD-TO-BOARD INTERCONNECT SYSTEMS,” by David H. Hartke and Joseph T. DiBene II, filed Aug. 2, 2001;

Application Ser. No. 09/910,524, entitled “HIGH PERFORMANCE THERMAL/MECHANICAL INTERFACE FOR FIXED-GAP REFERENCES FOR HIGH HEAT FLUX AND POWER SEMICONDUCTOR APPLICATIONS”, by Joseph T. DiBene, II, David H. Hartke, Wendell C. Johnson, Farhad Raiszadeh, Edward J. Darien and Jose B. San Andres, filed Jul. 20, 2001;

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001;

Application Serial No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001, which is a continuation-in-part of application Ser. No. 09/727,016, entitled “EMI CONTAIMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450, and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEAT-SINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000; and

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001; and

Application Serial No. 60/277,369, entitled “THERMAL-MECHANICAL MEASUREMENT AND ANALYSIS OF AN ADVANCED THERMAL INTERFACE MATERIAL CONSTRUCTION,” by Farhad Raiszadeh and Edward J. Derian, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEAT SINK FOR LOW PRESSURE DROP HIGH PERFORMANCE THERMAL MANAGEMENT ELECTRONIC ASSEMBLY SOLUTIONS,” by Joseph T. DiBene II and Farhad Raiszadeh, filed May 18, 2001;

Application Serial No. 60/299,573, entitled “MICRO I-PAK STACK UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke , filed Jun. 27, 2001;

Application Serial No. 60/304,929, entitled “BORREGO ARCHITECTURE,” by David H. Hartke and Joseph T. DiBene II, filed Jul. 11, 2001; and

Application Serial No. 60/304,930, entitled “MICRO I-PAK,” by Joseph T. DiBene II, Carl E. Hoge, David H. Hartke, Edward J. Derian, filed Jul. 11, 2001;

Application Ser. No. 09/921,152, entitled “HIGH SPEED AND DENSITY CIRCULAR CONNECTOR FOR BOARD-TO-BOARD INTERCONNECTION SYSTEMS,” by David H. Hartke and Joseph T. DiBene II, filed on Aug. 2, 2001, which is a continuation in part of the following patent applications:

Application Ser. No. 09/921,153 entitled “VAPOR CHAMBER WITH INTEGRATED PIN ARRAY”, by Joseph T. DiBene, II and Farhad Raiszadeh, filed on Aug. 2, 2001;

Application Ser. No. 09/910,524, entitled “HIGH PERFORMANCE THERMAL/MECHANICAL INTERFACE FOR FIXED-GAP REFERENCES FOR HIGH HEAT FLUX AND POWER SEMICONDUCTOR APPLICATIONS”, by Joseph T. DiBene, II, David H. Hartke, Wendell C. Johnson, Farhad Raiszadeh, Edward J. Darien and Jose B. San Andres, filed Jul. 20, 2001;

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001, which is a continuation-in-part of application Ser. No. 09/727,016, entitled “EMI CONTAINMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450; and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000;

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by David H. Hartke, James M. Broder, Joseph T. DiBene II, filed Feb. 6, 2001;

Application Serial No. 60/277,369, entitled “THERMAL-MECHANICAL MEASUREMENT AND ANALYSIS OF AN ADVANCED THERMAL INTERFACE MATERIAL CONSTRUCTION,” by Farhad Raiszadeh and Edward J. Derian, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEAT SINK FOR LOW PRESSURE DROP HIGH PERFORMANCE THERMAL MANAGEMENT ELECTRONIC ASSEMBLY SOLUTIONS,” by Joseph T. DiBene II and Farhad Raiszadeh, filed May 18, 2001;

Application Serial No. 60/299,573, entitled “MICRO I-PAK STACK UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001; and

Application Serial No. 60/304,930, entitled “MICRO I-PAK,” by Joseph T. DiBene II, Carl E. Hoge, David H. Hartke, Edward J. Derian, filed Jul. 11, 2001;

Application Ser. No. 10/022,454, entitled “ULTRA LOW IMPEDANCE POWER INTERCONNECTION SYSTEM FOR ELECTRONIC PACKAGING,” by Joseph T. DiBene II, David H. Hartke, Carl E. Hoge, and Edward J. Derian, filed Oct. 30, 2001, which is a continuation in part of the following U.S. Patent Applications:

Application Ser. No. 09/818,173, entitled “INTER-CIRCUIT ENCAPSULATED PACKAGING,” by Joseph T. DiBene, II and David H. Hartke, filed Mar. 26, 2001;

Application Ser. No. 09/921,152, entitled “HIGH SPEED AND DENSITY CIRCULAR CONNECTOR FOR BOARD-TO-BOARD INTERCONNECTION SYSTEMS,” by David H. Hartke and Joseph T. DiBene II, filed on Aug. 2, 2001;

Application Ser. No. 09/921,153 entitled “VAPOR CHAMBER WITH INTEGRATED PIN ARRAY”, by Joseph T. DiBene, II and Farhad Raiszadeh, filed on Aug. 2, 2001;

Application Ser. No. 09/910,524, entitled “HIGH PERFORMANCE THERMAL/MECHANICAL INTERFACE FOR FIXED-GAP REFERENCES FOR HIGH HEAT FLUX AND POWER SEMICONDUCTOR APPLICATIONS”, by Joseph T. DiBene, II, David H. Hartke, Wendell C. Johnson, Farhad Raiszadeh, Edward J. Darien and Jose B. San Andres, filed Jul. 20, 2001;

Application Ser. No. 09/885,780, entitled “INTER-CIRCUIT ENCAPSULATED PACKAGING,” by Joseph T. DiBene II and David H. Hartke, filed Jun. 19, 2001, which is a continuation of application Ser. No. 09/353,428, entitled “INTER-CIRCUIT ENCAPSULATED PACKAGING,” by Joseph T. DiBene II and David H. Hattke, filed Jul. 15, 1999 and now issued as U.S. Pat. No. 6,304,450;

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001, which is a continuation-in-part of application Ser. No. 09/727,016, entitled “EMI CONTAINMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450; and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000;

Application Serial No. 60/266,941, entitled “MECHANICAL INTERCONNECTION TECHNOLOGIES USING FLEX CABLE INTERCONNECT FOR DELIVERY IN ‘INCEP’ INTEGRATED ARCHITECTURE,” by David H. Hartke, James M. Broder, Joseph T. DiBene II, filed Feb. 6, 2001;

Application Serial No. 60/277,369, entitled “THERMAL-MECHANICAL MEASUREMENT AND ANALYSIS OF ADVANCED THERMAL INTERFACE MATERIAL CONSTRUCTION,” by Farhad Raiszadeh and Edward J. Derian, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEATSINK FOR LOW PRESSURE DROP HIGH PERFORMANCE THERMAL MANAGEMENT ELECTRONIC ASSEMBLY SOLUTIONS,” by Joseph T. DiBene II and Farhad Raiszadeh, filed May 18, 2001;

Application Serial No. 60/299,573, entitled “MICRO I-PAK STACK UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001;

Application Serial No. 60/304,930, entitled “MICRO I-PAK,” by Joseph T. DiBene II, Carl E. Hoge, David H. Hartke, Edward J. Derian, filed Jul. 11, 2001; and

Application Serial No. 60/310,038, entitled “TOOL-LESS CONCEPTS FOR BORREGO,” by Edward J. Derian and Joseph T. DiBene II, filed Aug. 3, 2001;

Application Serial No. 60/313,338, entitled “TOOL-LESS PRISM IPA ASSEMBLY TO SUPPORT IA64 MCKINLEY MICROPROCESSOR,” by David H. Hartke and Edward J. Derian, filed Aug. 17, 2001; and

Application Serial No. 60/338,004, entitled “MICRO-SPRING CONFIGURATIONS FOR POWER DELIVERY FROM VOLTAGE REGULATOR MODULES TO INTEGRATED CIRCUITS AND MICROPROCESSORS,” by Joseph T. DiBene II, David H. Hartke, Carl E. Hoge, and Edward J. Derian, filed Nov. 8, 2001;

Application Ser. No. 10/036,957, entitled “ULTRA-LOW IMPEDANCE POWER INTERCONNECTION SYSTEM FOR ELECTRONIC PACKAGES,” by Joseph T. DiBene II, David H. Hartke, Carl E. Hoge, and Edward J. Derian, filed Dec. 20, 2001, which is a continuation-in-part of the following patent applications:

Application Ser. No. 10/022,454, entitled “ULTRA LOW IMPEDANCE POWER INTERCONNECTION SYSTEM FOR ELECTRONIC PACKAGING,” by Joseph T. DiBene II, David H. Hartke, Carl E. Hoge, and Edward J. Derian, filed Oct. 30, 2001;

Application Ser. No. 09/818,173, entitled “INTER-CIRCUIT ENCAPSULATED PACKAGING,” by Joseph T. DiBene, II and David H. Hartke, filed Mar. 26, 2001;

Application Ser. No. 09/921,152, entitled “HIGH SPEED AND DENSITY CIRCULAR CONNECTOR FOR BOARD-TO-BOARD INTERCONNECTION SYSTEMS,” by David H. Hartke and Joseph T. DiBene II, filed on Aug. 2, 2001;

Application Ser. No. 09/921,153 entitled “VAPOR CHAMBER WITH INTEGRATED PIN ARRAY”, by Joseph T. DiBene, II and Farhad Raiszadeh, filed on Aug. 2, 2001;

Application Ser. No. 09/910,524, entitled “HIGH PERFORMANCE THERMAL/MECHANICAL INTERFACE FOR FIXED-GAP REFERENCES FOR HIGH HEAT FLUX AND POWER SEMICONDUCTOR APPLICATIONS”, by Joseph T. DiBene, II, David H. Hartke, Wendell C. Johnson, Farhad Raiszadeh, Edward J. Darien and Jose B. San Andres, filed Jul. 20, 2001;

Application Ser. No. 09/885,780, entitled “INTER-CIRCUIT ENCAPSULATED PACKAGING,” by Joseph T. DiBene II and David H. Hartke, filed Jun. 19, 2001, which is a continuation of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001, which is a continuation-in-part of application Ser. No. 09/727,016, entitled “EMI CONTAINMENT USING INTER-CIRCUIT ENCAPSULATED PACKAGING TECHNOLOGY,” by Joseph T. DiBene II and David H. Hartke, filed Nov. 28, 2000, and a continuation-in-part of application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II and David H. Hartke, filed Feb. 16, 2001, and a continuation in part of application Ser. No. 09/432,878, entitled “INTER-CIRCUIT ENCAPSULATED PACKAGING FOR POWER DELIVERY”, by Joseph T. DiBene II and David H. Hartke, filed Nov. 2, 1999, which is a continuation in part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999, which is a continuation-in-part of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450; and which claims priority to the following U.S. Provisional Patent Applications:

Application Serial No. 60/187,777, entitled “NEXT GENERATION PACKAGING FOR EMI CONTAINMENT, POWER DELIVERY, AND THERMAL DISSIPATION USING INTER-CIRCUIT ENCAPSULATED PACKAGING TECHNOLOGY,” by Joseph T. DiBene II and David H. Hartke, filed Mar. 8, 2000;

Application Serial No. 60/196,059, entitled “EMI FRAME WITH POWER FEED-THROUGH AND THERMAL INTERFACE MATERIAL IN AN AGGREGATE DIAMOND MIXTURE,” by Joseph T. DiBene II and David H. Hartke, filed Apr. 10, 2000;

Application Serial No. 60/219,813, entitled “HIGH-CURRENT MICROPROCESSOR POWER DELIVERY SYSTEMS,” by Joseph T. DiBene II, filed Jul. 21, 2000;

Application Serial No. 60/222,386, entitled “HIGH DENSITY CIRCULAR ‘PIN’ CONNECTOR FOR HIGH SPEED SIGNAL INTERCONNECT,” by David H. Hartke and Joseph T. DiBene II, filed Aug. 2, 2000;

Application Serial No. 60/222,407, entitled “VAPOR HEATSINK COMBINATION FOR HIGH EFFICIENCY THERMAL MANAGEMENT,” by David H. Hartke and Joseph T. DiBene II, filed Aug. 2, 2000; and

Application Serial No. 60/232,971, entitled “INTEGRATED POWER DISTRIBUTION AND SEMICONDUCTOR PACKAGE,” by Joseph T. DiBene II, James J. Hjerpe, filed Sep. 14, 2000;

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000;

Application Serial No. 60/266,941, entitled “MECHANICAL INTERCONNECTION TECHNOLOGIES USING FLEX CABLE INTERCONNECT FOR DELIVERY IN ‘INCEP’ INTEGRATED ARCHITECTURE,” by David H. Hartke, James M. Broder, Joseph T. DiBene II, filed Feb. 6, 2001;

Application Serial No. 60/277,369, entitled “THERMAL-MECHANICAL MEASUREMENT AND ANALYSIS OF ADVANCED THERMAL INTERFACE MATERIAL CONSTRUCTION,” by Farhad Raiszadeh and Edward J. Derian, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEATSINK FOR LOW PRESSURE DROP HIGH PERFORMANCE THERMAL MANAGEMENT ELECTRONIC ASSEMBLY SOLUTIONS,” by Joseph T. DiBene II and Farhad Raiszadeh, filed May 18, 2001;

Application Serial No. 60/299,573, entitled “MICRO I-PAK STACK UP ARCHITECTURE,” by Joseph T. DiBene II, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001;

Application Serial No. 60/304,930, entitled “MICRO I-PAK,” by Joseph T. DiBene II, Carl E. Hoge, David H. Hartke, Edward J. Derian, filed Jul. 11, 2001;

Application Serial No. 60/310,038, entitled “TOOL-LESS CONCEPTS FOR BORREGO,” by Edward J. Derian and Joseph T. DiBene II, filed Aug. 3, 2001;

Application Serial No. 60/313,338, entitled “TOOL-LESS PRISM IPA ASSEMBLY TO SUPPORT IA64 MCKINLEY MICROPROCESSOR,” by David H. Hartke and Edward J. Derian, filed Aug. 17, 2001; and

Application Serial No. 60/338,004, entitled “MICRO-SPRING CONFIGURATIONS FOR POWER DELIVERY FROM VOLTAGE REGULATOR MODULES TO INTEGRATED CIRCUITS AND MICROPROCESSORS,” by Joseph T. DiBene II, David H. Hartke, Carl E. Hoge, and Edward J. Derian, filed Nov. 8, 2001; and

Application Ser. No. 10/005,024, entitled “INTEGRATED POWER DELIVERY WITH FLEX CIRCUIT INTERCONNECTION FOR HIGH DENSITY HIGH POWER CIRCUITS FOR INTEGRATED CIRCUITS AND SYSTEMS” by Joseph T. DiBene II and David H. Hartke, filed Dec. 4, 2001, which is a continuation-in-part of the following patent applications:

Application Ser. No. 09/885,780, entitled “INTER-CIRCUIT ENCAPSULATED PACKAGING,” by Joseph T. DiBene II and David H. Hartke, filed Jun. 19, 2001, which is a continuation of application Ser. No. 09/353,428, entitled “INTER-CIRCUIT ENCAPSULATED PACKAGING,” by Joseph T. DiBene II and David H. Hartke, filed Jul. 15, 1999 and now issued as U.S. Pat. No. 6,304,450;

Application Ser. No. 09/432,878, entitled “INTER-CIRCUIT ENCAPSULATED PACKAGING FOR POWER DELIVERY,” by Joseph T. DiBene II and David H. Hartke, filed Nov. 2, 1999;

Application Ser. No. 09/727,016, entitled “EMI CONTAINMENT USING INTER-CIRCUIT ENCAPSULATED PACKAGING TECHNOLOGY” by Joseph T. DiBene II and David Hartke, filed Nov. 28, 2000;

Application Ser. No. 09/785,892, entitled “METHOD AND APPARATUS FOR PROVIDING POWER TO A MICROPROCESSOR WITH INTEGRATED THERMAL AND EMI MANAGEMENT,” by Joseph T. DiBene II, David H. Hartke, James J. Hjerpe Kaskade, and Carl E. Hoge, filed Feb. 16, 2001;

Application Ser. No. 09/798,541, entitled “THERMAL/MECHANICAL SPRINGBEAM MECHANISM FOR HEAT TRANSFER FROM HEAT SOURCE TO HEAT DISSIPATING DEVICE,” by Joseph T. DiBene II, David H. Hartke, Wendell C. Johnson, and Edward J. Derian, filed Mar. 2, 2001;

Application Ser. No. 09/801,437, entitled “METHOD AND APPARATUS FOR DELIVERING POWER TO HIGH PERFORMANCE ELECTRONIC ASSEMBLIES” by Joseph T. DiBene II, David H. Hartke, Carl E. Hoge, James M. Broder, Edward J. Derian, Joseph S. Riel, and Jose B. San Andres, filed Mar. 8, 2001;

Application Ser. No. 09/802,329, entitled “METHOD AND APPARATUS FOR THERMAL AND MECHANICAL MANAGEMENT OF A POWER REGULATOR MODULE AND MICROPROCESSOR IN CONTACT WITH A THERMALLY CONDUCTING PLATE” by Joseph T. DiBene II and David H. Hartke, filed Mar. 8, 2001;

Application Ser. No. 09/910,524, entitled “HIGH PERFORMANCE THERMAL/MECHANICAL INTERFACE FOR FIXED-GAP REFERENCES FOR HIGH HEAT FLUX AND POWER SEMICONDUCTOR APPLICATIONS”, by Joseph T. DiBene, II, David H. Hartke, Wendell C. Johnson, Farhad Raiszadeh, Edward J. Darien and Jose B. San Andres, filed Jul. 20, 2001;

Application Ser. No. 09/921,153 entitled “VAPOR CHAMBER WITH INTEGRATED PIN ARRAY”, by Joseph T. DiBene, II and Farhad Raiszadeh, filed on Aug. 2, 2001;

Application Ser. No. 09/818,173, entitled “INTER-CIRCUIT ENCAPSULATED PACKAGING,” by David H. Hartke and Joseph T. DiBene II, filed Mar. 26, 2001;

Application Ser. No. 09/921,152, entitled “HIGH SPEED AND DENSITY CIRCULAR CONNECTOR FOR BOARD-TO-BOARD INTERCONNECTION SYSTEMS,” by David H. Hartke and Joseph T. DiBene II, filed on Aug. 2, 2001;

Application Ser. No. 09/921,153, entitled “VAPOR CHAMBER WITH INTEGRATED PIN ARRAY,” by Joseph T. DiBene II, and Farhad Raiszadeh, filed Aug. 2, 2001,

Application Ser. No. 10/022,454, entitled “ULTRA-LOW IMPEDANCE POWER INTERCONNECTION SYSTEM FOR ELECTRONIC PACKAGING,” by Joseph T. DiBene II, David H. Hartke, Carl E. Hoge, and Edward J. Derian, filed Oct. 30, 2001; and which also claims benefit of and incorporates by reference the following U.S. Provisional Patent Applications:

Application Serial No. 60/251,222, entitled “INTEGRATED POWER DELIVERY WITH FLEX CIRCUIT INTERCONNECTION FOR HIGH DENSITY POWER CIRCUITS FOR INTEGRATED CIRCUITS AND SYSTEMS,” by Joseph T. DiBene II and David H. Hartke, filed Dec. 4, 2000;

Application Serial No. 60/251,223, entitled “MICRO-I-PAK FOR POWER DELIVERY TO MICROELECTRONICS,” by Joseph T. DiBene II and Carl E. Hoge, filed Dec. 4, 2000;

Application Serial No. 60/251,184, entitled “MICROPROCESSOR INTEGRATED PACKAGING,” by Joseph T. DiBene II, filed Dec. 4, 2000;

Application Serial No. 60/266,941, entitled “MECHANICAL INTERCONNECTION TECHNOLOGIES USING FLEX CABLE INTERCONNECT FOR POWER DELIVERY IN ‘INCEP’ INTEGRATED ARCHITECTURE,” by Joseph T. DiBene II, David H. Hartke, and James M. Broder, filed Feb. 6, 2001;

Application Serial No. 60/277,369, entitled “THERMAL-MECHANICAL MEASUREMENT AND ANALYSIS OF ADVANCED THERMAL INTERFACE MATERIAL CONSTRUCTION,” by Joseph T. DiBene II, David H. Hartke and Farhad Raiszadeh, filed Mar. 19, 2001;

Application Serial No. 60/287,860, entitled “POWER TRANSMISSION DEVICE,” by Joseph T. DiBene II, David H. Hartke, Carl E. Hoge, and Edward J. Derian, filed May 1, 2001;

Application Serial No. 60/291,749, entitled “MICRO I-PAK ARCHITECTURE HAVING A FLEXIBLE CONNECTOR BETWEEN A VOLTAGE REGULATION MODULE AND SUBSTRATE,” by Joseph T. DiBene II, filed May 16, 2001;

Application Serial No. 60/291,772, entitled “I-PAK ARCHITECTURE POWERING MULTIPLE DEVICES,” by Joseph T. DiBene II, David H. Hartke, Carl E. Hoge, and Edward J. Derian, filed May 16, 2001;

Application Serial No. 60/292,125, entitled “VORTEX HEATSINK FOR LOW PRESSURE DROP HIGH PERFORMANCE THERMAL MANAGEMENT ELECTRONIC ASSEMBLY SOLUTIONS,” by Joseph T. DiBene II, Farhad Raiszadeh, filed May 18, 2001;

Application Serial No. 60/299,573, entitled “IMPROVED MICRO-I-PAK STACK-UP ARCHITECTURE,” by Joseph T. DiBene, Carl E. Hoge, and David H. Hartke, filed Jun. 19, 2001;

Application Serial No. 60/301,753, entitled “INTEGRATED POWER DELIVERY USING HIGH PERFORMANCE LINEAR REGULATORS ON PACKAGE WITH A MICROPROCESSOR,” by Joseph T. DiBene II, Carl E. Hoge, and David H. Hartke, filed Jun. 27, 2001;

Application Serial No. 60/304,929, entitled “BORREGO ARCHITECTURE,” by David H. Hartke and Joseph T. DiBene II, filed Jul. 11, 2001;

Application Serial No. 60/304,930, entitled “MICRO-I-PAK,” by Joseph T. DiBene II, Carl E. Hoge, David H. Hartke, and Edward J. Derian, filed Jul. 11, 2001;

Application Serial No. 60/310,038, entitled “TOOL-LESS CONCEPTS FOR BORREGO,” by Edward J. Derian and Joseph T. DiBene II, filed Aug. 3, 2001;

Application Serial No. 60/313,338, entitled “TOOL-LESS PRISM IPA ASSEMBLY TO SUPPORT IA64 MCKINLEY MICROPROCESSOR,” by David H. Hartke and Edward J. Derian, filed Aug. 17, 2001; and

Application Serial No. 60/338,004, entitled “MICRO-SPRING CONFIGURATIONS FOR POWER DELIVERY FROM VOLTAGE REGULATOR MODULES TO INTEGRATED CIRCUITS AND MICROPROCESSORS,” by Joseph T. DiBene It, David H. Hartke, Carl E. Hoge, and Edward J. Derian, filed Nov. 8, 2001.

### BACKGROUND OF THE INVENTION

1. Field of the Invention

This invention relates in general to a method and apparatus for improving the packaging and distribution of power to high performance electronic circuits, and in particular, to a flexible circuit connection method for providing electrical power continuity between a voltage regulation module (VRM) and the substrate of an integrated circuit.

2. Description of the Related Art

As circuitry in electronics becomes more complex, packaging of the circuitry has become more difficult. The common method for packaging integrated circuits (ICs) and other electronic components is to mount them on printed circuit boards (PCBs) or other substrates such as ceramic or organic consisting of alternating conductive and non-conductive layers or planes sandwiched or bonded together to form a dense X-Y signal interconnect. For a number of years, the operating voltage of IC's was approximately 5 volts and the power consumption was generally less than 1 watt. This relatively high supply voltage and low power level allowed the packaging of a large number of ICs on a single PCB with power distribution incorporated into one or more of the PCB planes.

More recently advances in silicon fabrication techniques have permitted the manufacturer of high performance IC packages with operating voltages at or below 1 volt and power levels in excess of 100 watts. As described in co-pending and commonly assigned patent application Ser. No. 09/785,982, METHOD AND APPARATUS FOR PROVIDING POWER TO A MICROPROCESSOR WITH INTEGRATED THERMAL AND EMI MANAGEMENT, by Joseph T. DiBene II et al., filed Feb. 16, 2001, which application is hereby incorporated by reference, the transient current to some of these packages can approach hundreds of amps per microsecond. To assure optimum performance under these conditions, it is important that the electrical path from the power supply or VRM to the IC be designed to accommodate high current flow and low series inductance, two goals which are difficult to achieve at the same time. The present invention achieves both of these goals, while also allowing for a compact, integrated stack-up system design that permits thermal dissipation and control of electromagnetic interference (EMI).

### SUMMARY OF THE INVENTION

To address the requirements described above, the present invention discloses a method and apparatus for providing power from a first circuit board to a second circuit board. The apparatus comprises a flex circuit having a plurality of conductive paths formed by a plurality of first conductive areas electrically coupled to a plurality of second conductive areas wherein the plurality of first conductive areas permanently and electrically coupled to a plurality of first circuit board conductive pads and the plurality of second conductive areas disconnectably and electrically coupleable to at least one second circuit board conductive pad.

### BRIEF DESCRIPTION OF THE DRAWINGS

Referring now to the drawings in which like reference numbers represent corresponding parts throughout:

FIG. 1A is a two-dimensional section view illustrating an architecture in which the present invention may be usefully employed in delivering power to a microprocessor;

FIG. 1B is a section plan view of the microprocessor package illustrated in FIG. 1A which further illustrates the location of the applicable power connection pads on the microprocessor package associated with delivering power to the microprocessor shown in FIG. 1A;

FIG. 1C is a section plan view of the VRM package illustrated in FIG. 1A which further illustrates the location of the applicable power connection pads on the VRM associated with delivering power to the microprocessor shown in FIG. 1A;

FIG. 2 is a two-dimensional enlarged view of the flexible circuit power interconnect device illustrated in FIG. 1A showing the location of the flexible circuitry between the VRM and microprocessor package;

FIG. 3 is a further expanded two-dimensional enlarged view of the flexible circuit power interconnect device illustrated in FIG. 1A and FIG. 2 showing detail layer construction of the flexible circuit and a method of providing normal forces to the connectors utilizing an elastomer material;

FIG. 4 is a plan view of the flexible circuit power interconnect device before it is formed to the configuration shown in FIG. 3 illustrating the planar layer details including the interdigitated pad structures;

FIG. 5 illustrates an alternate method of providing normal force to the connectors illustrated in FIG. 3 in which a spring is used in place of the elastomer;

FIG. 6 is an expanded two-dimensional enlarged view of the flexible circuit power interconnect illustrating an alternate method of arranging the connectors on the microprocessor substrate to ease the alignment of the pads on the microprocessor substrate and the connector bumps on the flexible circuit power interconnect device;

FIG.7 is a section plan view of the microprocessor package illustrated in FIG. 6 which further illustrates the location of the applicable power connection pads on the microprocessor substrate for improved alignment;

FIG. 8 is a two-dimensional section view illustrating an alternate architecture in which the present invention may be usefully employed in delivering power to a microprocessor; and

FIG. 9 is an expanded two-dimensional enlarged view of the flexible circuit power interconnect device illustrated in FIG. 8 showing detail layer construction of the flexible circuit and a method of providing normal forces to the connectors.

### DETAILED DESCRIPTION OF PREFERRED EMBODIMENTS

In the following description, reference is made to the accompanying drawings which form a part hereof, and which is shown, by way of illustration, several embodiments of the present invention. It is understood that other embodiments may be utilized and structural changes may be made without departing from the scope of the present invention.

### Overview

The present invention discloses a method and apparatus for providing separable power interconnect from a first circuit board to a second circuit board utilizing flexible printed circuits. In one embodiment, the apparatus consists of a two conductive layer flexible circuit that is permanently attached to the first circuit board in an interdigitated pad structure and then formed into a ‘C’ or sideways ‘U’ shape such that the opposite end of the flexible circuit can then connect to a mating interdigitated pad structure on the second circuit board with an interposing method of providing normal forces to the connectors on the second circuit board.

The present invention discloses an alternate method of arranging the contacts on the second circuit board such as to mitigate alignment tolerances between the flexible circuit power interconnect and the second circuit board.

Finally, the present invention discloses a variation on the first approach where the flexible circuit power interconnect is permanently attached to the first circuit board and then extends in a proximate planar manner to the second circuit board such that that the interconnection distances are shortened resulting in reduced interconnect inductance.

### Detail Description of the Invention

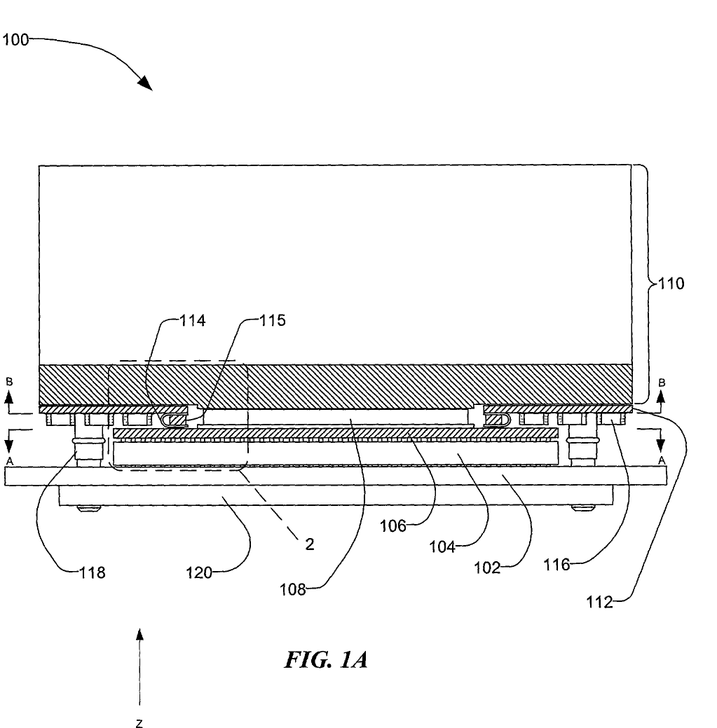

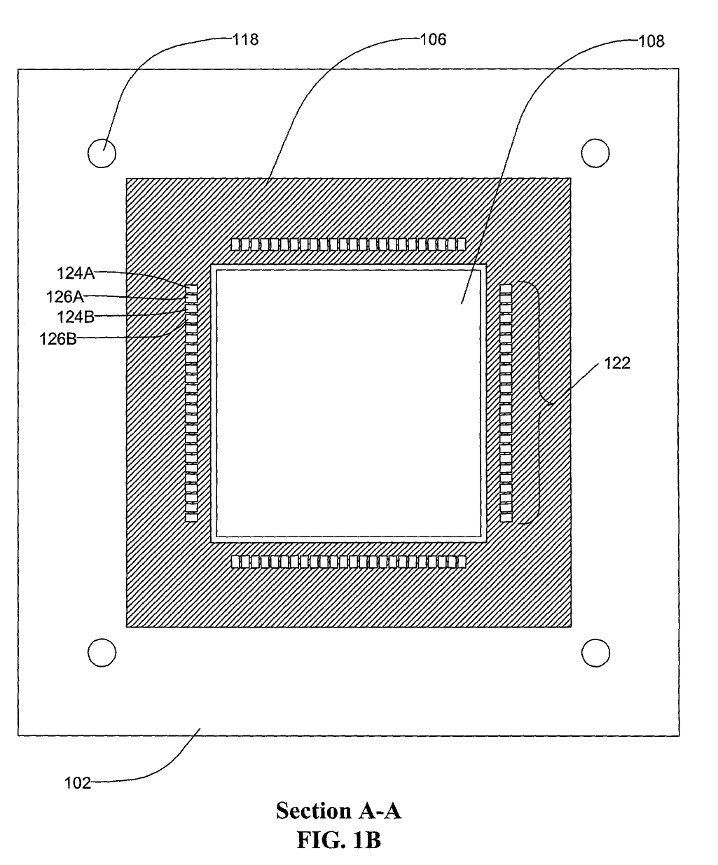

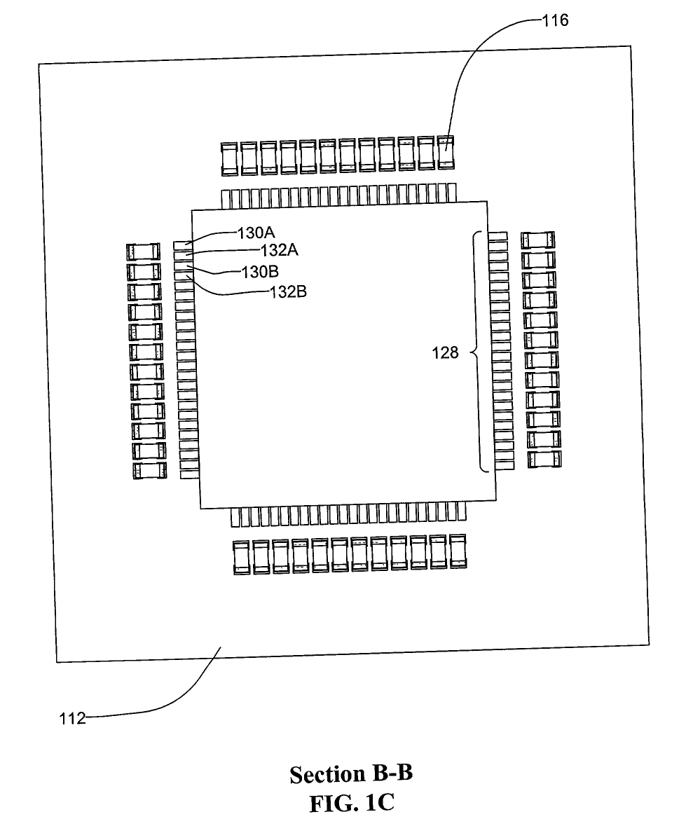

Referring to the drawings more particularly by reference numbers, FIG. 1 is an electronic package 100 of the present invention. The electronic package 100 contains a main circuit board 102 onto which is placed a connector 104 for interconnecting signals between another circuit board such as a microprocessor substrate 106 and the main circuit board 102. A lidded microprocessor 108 or other heat dissipating and power consuming device is attached to substrate 106.

Heatsink 110 is pressed against lidded microprocessor 108 in order to conduct heat from microprocessor 108. In order to provide power to microprocessor 108 a VRM 112 is located underneath the base of heatsink 110 and is concentrically located around lidded microprocessor 108 with a hole provided in the VRM 112 circuit board or substrate such that lidded microprocessor can project through to the base of heatsink 110. Components 116 attached to the substrate of VRM 112 represents both active and passive components associated with the functionality provided by the VRM 112. Heat-dissipating components 116 on VRM 112 are provided with a thermal conduction path to the base of heatsink 110.

The present invention provides a physically separable low impedance power path from the VRM 112 to the microprocessor substrate 106, while accommodating a ‘Z’ axis (or vertical) tolerance acceptance between the VRM substrate 112 and the microprocessor substrate 106. This is accomplished by flexible circuit assembly 114 that is permanently attached to VRM 112 while providing a separable connection to microprocessor substrate 106. Note that flexible circuit assembly 114 is preferably located around all four sides of the opening in VRM 112 to enhance the reduction in power interconnect impedance to lidded microprocessor 108.

This separable connection uses a normal force applied at the interconnection between the flexible circuit assembly 114 and the microprocessor substrate 106, which, in the illustrated embodiment, is supplied by the z-axis compressible or compliant elastomer 115 as shown. In order to provide compressive forces for the thermal interface between lidded microprocessor 108 and the base of heatsink 110 as well as the compressive forces required by compliant elastomer 115, spring loaded screw assemblies 118 react between the heatsink base and a bolster plate 120 which is located underneath main board 102 completing a force loop on the overall assembly 100. Alternate methods may be employed to achieve similar compressive forces.

FIG. 1B is a section view A-A as defined in FIG. 1A. This view looks down onto the microprocessor substrate 106, the lidded microprocessor 108 and the main board 102. Located on the top surface of microprocessor substrate 106 are a plurality of pads 124A and 124B (hereinafter alternatively collectively referred to as the first set of microprocessor substrate pads 124) and pads 126A and 126B (hereinafter alternatively collectively referred to as the second set of microprocessor substrate pads 126). In the illustrated embodiment, the plurality of pads are disposed in four groups 122 located around the periphery (typically four sides) of lidded microprocessor 108.

In one embodiment of the present invention, power interconnect impedance is reduced by assigning the first set of microprocessor substrate pads to carry power, and assigning the second set of microprocessor substrate pads to carry a ground signal, and by interleaving the first set of microprocessor substrate pads 124 with the second set of microprocessor substrate pads 126. This forms an alternating interdigitated pattern of power-ground power-ground terminals. While other patterns of ground and power are within the scope of the present invention, this connection scheme provides a power interconnection with a minimal loop area so as to reduce the interconnection inductance.

FIG. 1C is a section view B-B as defined in FIG. 1A. This view looks up into the VRM substrate 112. Located on the bottom surface of the VRM substrate 112 are four corresponding groups 128 of power connection pads 130A and 130B (collectively, alternatively referred to hereinafter as the first set of VRM pads 130) and 132A and 132B (collectively, alternatively referred to hereinafter as the second set of VRM pads 132). In accordance with the alternativing interdigitated pattern embodiment described above, the connection pads 130 and 132 may also be arranged in an alternating pattern of ground and power.

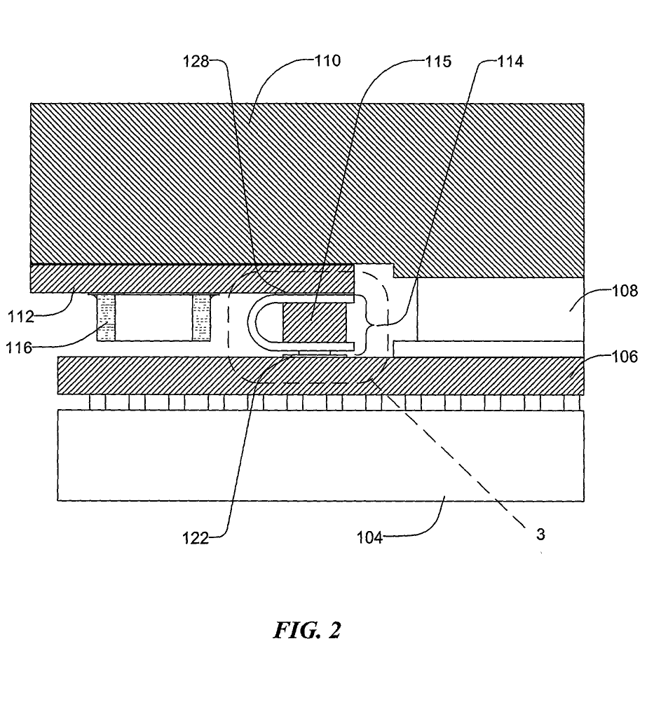

FIG. 2 is an enlarged sectional view of the flexible circuit assembly 114 and the surrounding elements. Note the power connection pads 122 on the processor substrate 106 and the power connection pads 128 on the VRM substrate 112. Located in between these two pads is the flexible circuit assembly 114 and the compliant elastomeric spring 115 which urges the lower half of the flexible circuit assembly 114 into contact with the pads of 122.

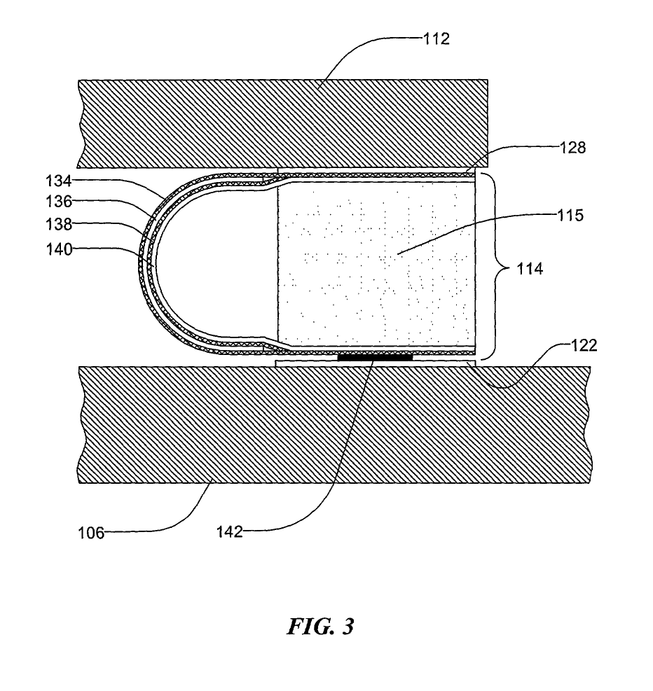

FIG. 3 is a still further enlarged sectional view of the flexible circuit assembly 114, showing conductive paths 134 and 138. The flexible circuit assembly 114 comprises of an outer conductive foil 134 which can be assigned a ground power potential, an insulative sheet 136 generally made of polyimide, an inner conductive foil 138 which can be assigned a power or voltage potential and a final insulative sheet 140 also generally made of polyimide. In the bent portion of the flex circuit, the inner conductive foil 138 and the outer conductive foil 134 are in different layers. However, the inner conductive foil 138 is merged into the same layer or plane as the outer conductive sheet 134 in the area proximate the substrate pads groups 122 and 128.

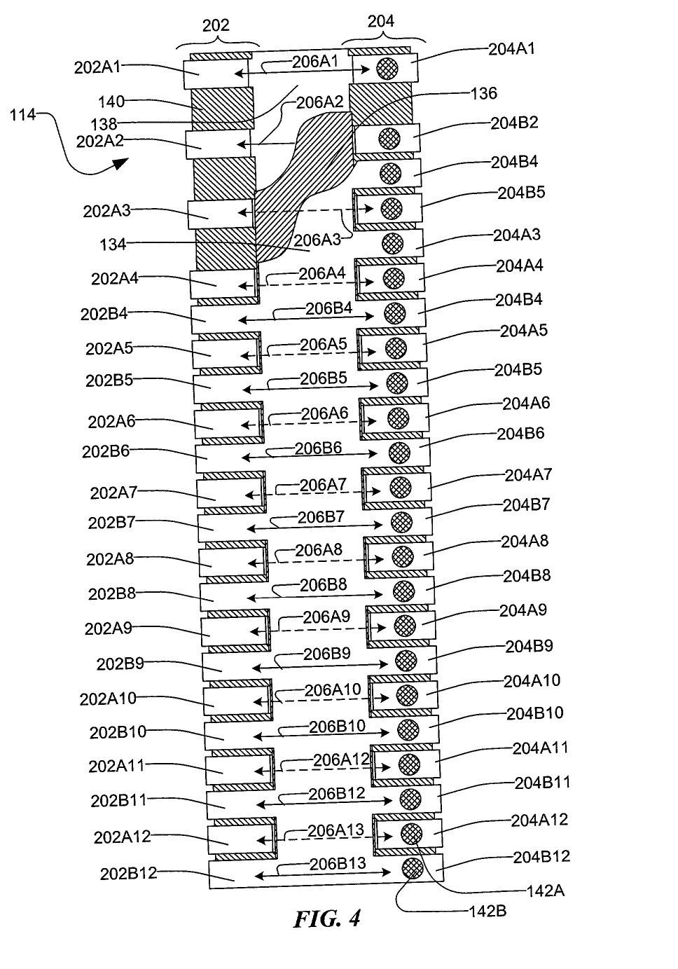

This is possible because the conductive flexible foils 134 and 138 consist of interdigitated conductive areas in these regions, as is further illustrated in FIG. 4 and the accompanying text.

In the illustrated embodiment, the lower portions of the flexible circuits proximate and disposed over substrate pad group 122 have conductive bumps 142 formed on their tabs to act as a reliable electric contacts between the contact bumps 142 and the substrate pads 122. Generally, the surfaces of both the contact bumps 142 and the substrate pads 122 are plated with gold over a nickel undercoat to provide long term reliable electrical connection.

The interdigitated tabs on the upper portions of the flexible circuits 134 and 138 over the substrate pads 128 are permanently attached to each other using soldering methods. As previously noted, the elastomeric spring 115 provides a normal force to the contact interface between bump 142 and substrate pad 122.

FIG. 4 illustrates the flexible circuit assembly 114, including four layers 134, 136, 138 and 140. Note that this figure depicts assembly 114 in the flat form, that is, before it is folded over to form the ‘U’ shape illustrated in FIG. 1 through FIG. 3. The flexible circuit assembly 114 includes a plurality of first conductive areas 202 and a plurality of second conductive areas 204. The first conductive areas 202 and the second conductive areas implement a plurality of conductive paths, including a first set of conductive paths (e.g. 206A1-206A12, alternatively collectively referred to hereinafter as the first set of conductive paths 206A) and a second set of conductive paths (e.g. 206B1-206B12, collectively referred to hereinafter as the second set of conductive paths 206B). The first set of conductive paths 206A is formed by a first subset of the plurality of first conductive areas (e.g. 202A1-202A12, alternatively collectively referred to hereinafter as the first subset of the plurality of first conductive areas 202A) electrically coupled to a first subset of the plurality of second conductive areas (e.g. 204A1-204A12, alternatively collectively referred to hereinafter as the second set of conductive areas 204A). The second set of conductive paths 206B is formed by a the second subset of the plurality of first conductive areas (e.g. 202B1-202B12, alternatively collectively referred to hereinafter as the first set of conductive areas 202B) electrically coupled to a second subset of the plurality of second conductive areas (e.g. 204A1-204A12, alternatively collectively referred to hereinafter as the second set of conductive areas 204A).

The first set of conductive paths are implemented by conductive foil 134, and the each of the second set of conductive paths are implemented by conductive foil 138, which is electrically isolated from the first conductive foil 134 by insulative layer 136. As can now be better seen, the tabs on the two conductive foils 134 and 138 are interdigitated at each end terminus.

Note, also, the contact bumps 142A and 142B which are a part of ground conductive foils 136 and power or voltage conductive foil 138 respectively. The contact bumps 142A and 142B can be fabricated as an additional plating process in the fabrication of conductive foils 136 and 138 or, may consist of separate fabricated contacts that are later assembled to conductive foils 136 and 138. One such example of the latter are contacts made by INTERCON SYSTEMS of Harrisburg, Pa.

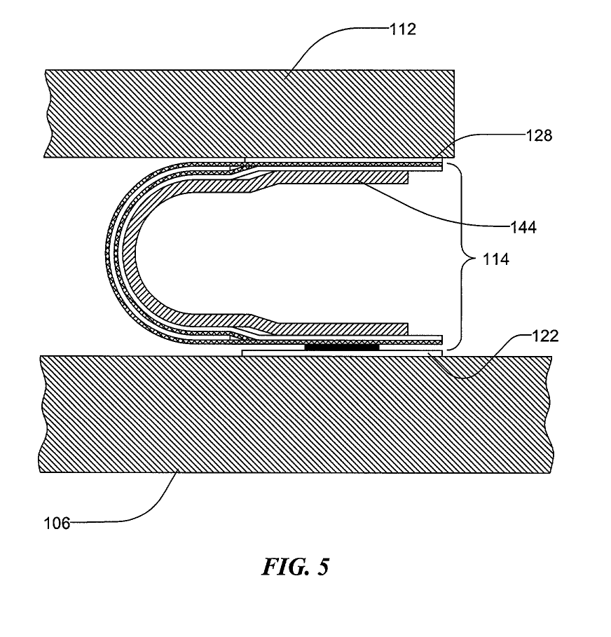

FIG. 5 illustrates a method by which the elastomeric spring 115 in the preceding figures can be replaced by a ‘U’ shaped spring 144 which is nestled within the inner portion of the ‘U’ shape of the flexible circuit assembly 114. Such a spring may be conveniently made of Beryllium Copper or stainless steel. In either case, the upper and middle portion of the spring 144 would be continuous along its length whereas the lower portion is best made by creating individual tabs that correspond and align with the tabs on the flexible conductive circuits 134 and 138 so as to create independent normal mode forces to each contact bump 142 along the length of the flexible circuits 134 and 138.

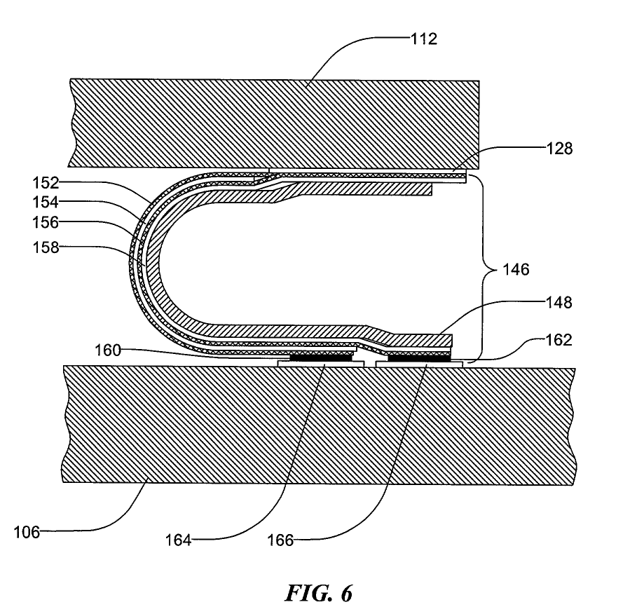

FIG. 6 illustrates an alternative separable contact arrangement where the separable contacts to the microprocessor substrate 106 are arranged in two adjacent rows one displaced behind the other. Flexible circuit assembly 146 is similar to flexible circuit assembly 114 and is joined to VRM substrate 112 at pads 128 using an interdigitated tab pattern as before. However, outer conductive foil 152 which can be assigned a ground power potential is terminated at a continuous pad 164 on microprocessor substrate 106 through contact bumps 160. An insulative sheet 154 isolates the inner conductive foil 156 which can be assigned a power or voltage potential and is terminated at continuous pad 166 on microprocessor substrate 106 through contact bumps 162 which are behind continuous pad 164. A final insulative sheet 158 completes flexible circuit assembly 146. Note that the terminus of conductive sheets 152 and 156 need not be interdigitated at contact bumps 160 and 162. ‘U’ shaped spring 148 illustrates one method by which normal forces can be applied to contact bumps 164 and 166. Again, individual tabs on ‘U’ shape spring 148 may be desirous to achieve independent forces to each contact bump.

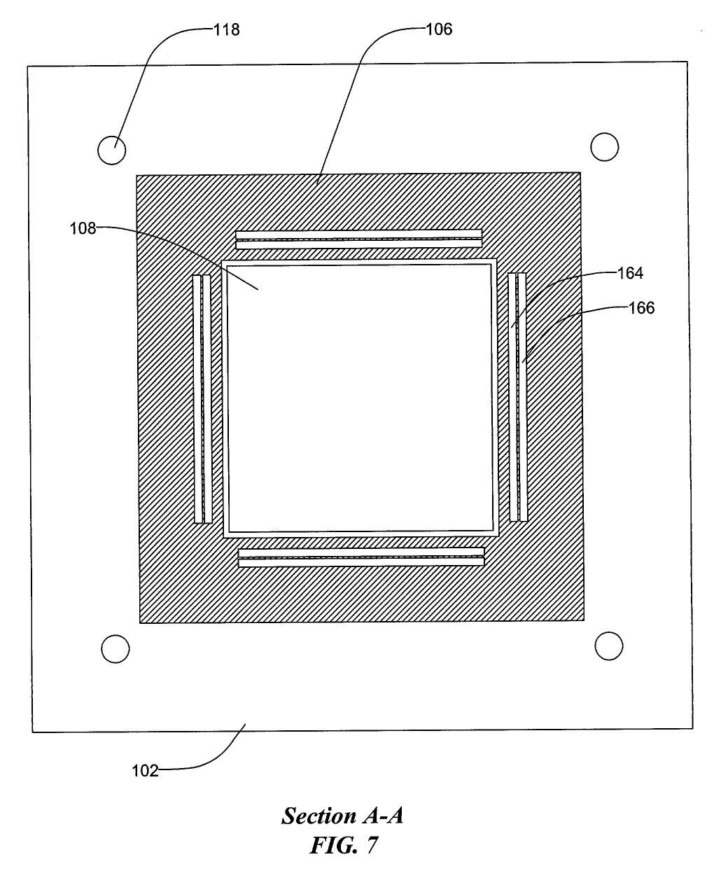

FIG. 7 is a section view A-A as defined in FIG. 1A for the contact arrangement described in FIG. 6. Here the contact pads 164 and 166 on substrate 106 are continuous strips along each side of lidded microprocessor 108. The result of the preceding arrangement is to permit a greater range of X-Y or planar misalignment between contact bumps 160/162 and contact pads 164/166. Also, layout and fabrication of substrate 106 may be eased by such an arrangement.

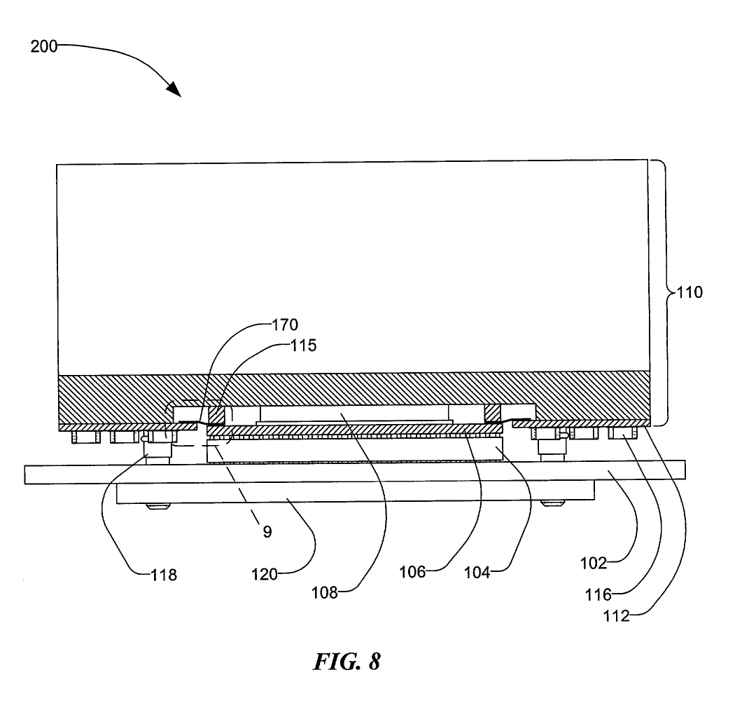

FIG. 8 illustrates an alternative arrangement 200 of the flexible circuit assemblies 114 and 146. In this arrangement flexible circuit assembly 170 is joined to the top inside edge of the aperture in VRM substrate 112 and is directed over the top outside edge of microprocessor substrate 106. This may result in a larger aperture in VRM substrate 112 but a shorter path length in flexible circuit assembly 170 resulting in a slightly lower power connection inductance between VRM 112 and processor substrate 106.

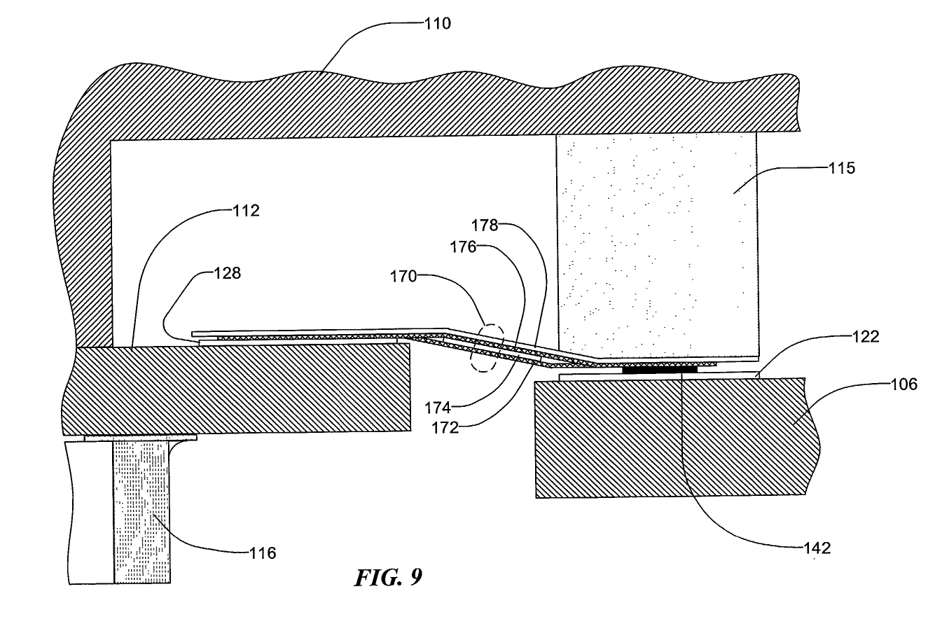

FIG. 9 is an expanded view of the flexible circuit assembly 170 and the surrounding interfaces. The flexible circuit assembly 170 consists of a lower conductive foil 172 which can be assigned a ground power potential, an insulative sheet 174, an upper conductive foil 176 which can be assigned a power or voltage potential and a final insulative sheet 178. As before the upper conductive sheet is merged into the same plane as the lower conductive sheet around pads 122 and 128. Both ends of conductive foils 172 and 176 are interdigitated as before and the left end of the interdigitated tabs on foils 172 and 176 are soldered to pads 128 on VRM substrate 112. The right end of conductive foils 172 and 176 have contact bumps 142 fabricated on the bottom of the interdigitated tabs. Finally, compliant elastomer 115 or a spring equivalent is used to supply normal forces to the contact bumps 142 and the pads 122.

### Conclusion

This concludes the description of the preferred embodiments of the present invention. The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. An apparatus for providing power from a first circuit board to a second circuit board, comprising:
a flex circuit having a plurality of conductive paths formed by a plurality of first conductive areas electrically coupled to a plurality of second conductive areas;
the plurality of first conductive areas permanently and electrically coupled to a plurality of first circuit board conductive pads;
the plurality of second conductive areas disconnectably and electrically coupleable to at least one second circuit board conductive pad.

2. The apparatus of claim 1, wherein:
the plurality of conductive paths includes a first set of conductive paths and a second set of conductive paths,
the first set of conductive paths formed by a first set of the plurality of first conductive areas electrically coupled to a first set of the plurality of the second conductive areas
and a second set of conductive paths formed by a second set of first conductive areas electrically coupled to a second set of second conductive areas;
the first set of conductive paths describe a power path between the first circuit board and the second circuit board; and
the second set of conductive paths describe a ground path between the first circuit board and the second circuit board.

3. The apparatus of claim 2, wherein the first set of conductive paths are interdigitated with the second set of conductive paths.

4. The apparatus of claim 2, wherein
the first set of the plurality of second conductive areas is disconnectably and electrically coupleable with a first set of second circuit board conductive pads; and
the second set of the plurality of second conductive areas is disconnectably and electrically coupleable with a second set of second circuit board conductive pads.

5. The apparatus of claim 2, wherein:
the first set of the plurality of second conductive areas is disconnectably and electrically coupleable with a first second circuit board conductive pad; and
the second set of the plurality of second conductive areas is disconnectably and electrically coupleable with a second second circuit board conductive pad adjacent the first second circuit board conductive pad.

6. The apparatus of claim 2, wherein the flex circuit comprises a first portion having the plurality of first conductive areas, a second portion having the plurality of second conductive areas, and a third portion having a plurality of conductive layers interconnecting the first conductive areas and the second conductive areas.

7. The apparatus of claim 1, wherein the flex circuit is disposed between the first circuit board and the second circuit board.

8. The apparatus of claim 7, wherein the first circuit board is disposed above the second circuit board.

9. The apparatus of claim 7, wherein the first circuit board comprises an aperture, and the second circuit board is disposed at least partially through the aperture.

10. The apparatus of claim 1, further comprising:
a z-axis compressible member, disposed adjacent the second plurality of conductive areas, the z-axis compressible member urging disconnectable and electrical contact between the second plurality of conductive areas and the at least one second circuit board conductive pad.

11. The apparatus of claim 10, wherein the flex circuit is folded into a C-shape, and the z-axis compressible member is disposed between the first plurality of conductive areas and the second plurality of conductive areas.

12. The apparatus of claim 11, wherein the z-axis compressible member comprises a z-axis compressible spring.

13. The apparatus of claim 12, wherein the z-axis compressible spring comprises a C-shape.

14. The apparatus of claim 11, wherein the z-axis compressible member comprises an elastomer.

15. The apparatus of claim 10, wherein the z-axis compressible member and the flex circuit accommodate build tolerances along a z-axis.

16. The apparatus of claim 10, where at least one of the second conductive areas comprises a contact bump.
